(19) United States
(12) Patent Application Publication
(10) Pub. No.: US 2024/0213295 A1
(43) Pub. Date: Jun. 27, 2024

(54) LIGHT-EMITTING DEVICE AND LIGHT-EMITTING APPARATUS INCLUDING THE SAME

(71) Applicant: AUO Corporation, Hsinchu (TW)

(72) Inventors: Yi-Hong Chen, Hsinchu (TW); Yu-Hsin Huang, Hsinchu (TW); Chia-An Lee, Hsinchu (TW); YinYu Chen, Hsinchu (TW); Kuan-Heng Lin, Hsinchu (TW)

(73) Assignee: AUO Corporation, Hsinchu (TW)

(21) Appl. No.: 18/337,050

(22) Filed: Jun. 19, 2023

(30) Foreign Application Priority Data
Dec. 22, 2022 (TW) 111149434

(51) Int. Cl. H01L 27/15

(52) U.S. Cl. CPC H01L 27/156

(57) ABSTRACT

A light-emitting device includes a carrier, a reflection layer, a common electrode and a first semiconductor stack. The carrier has a light-emitting region, an electrical connection region and a trench, which separates the light-emitting region from the electrical connection region. The reflection layer is disposed on a sidewall of the trench. The common electrode is disposed in the electrical connection region. The first semiconductor stack is disposed in the light-emitting region, wherein a first type semiconductor layer of the first semiconductor stack is electrically connected to the common electrode. A light-emitting apparatus including the light-emitting device is also provided.

### CROSS-REFERENCE TO RELATED APPLICATION

This application claims the priority benefit of Taiwan application serial no. 111149434, filed on Dec. 22, 2022. The entirety of the above-mentioned patent applications is hereby incorporated by reference herein and made a part of this specification.

### BACKGROUND

### Technical Field

The disclosure relates to a photoelectric device and a photoelectric apparatus including the same and, in particular, to a light-emitting device and a light-emitting apparatus including the same.

### Description of Related Art

Micro-light-emitting diode (Micro-LED) light-emitting apparatus has the advantages of power saving, high efficiency, high luminance and fast response time. Currently, for the fabrication of Micro-LED light-emitting apparatus, it is necessary to arrange the Micro-LEDs on the circuit substrate and complete the circuit connection between the Micro-LEDs and the circuit substrate. Further, it needs to configure the isolation structure between the Micro-LEDs to avoid light mixing. Moreover, if a full-color display apparatus is to be fabricated, the planarization layer must be formed before the formation of the color conversion structures, which is a quite cumbersome production process. In addition, the resulting pixel area cannot be reduced further, so it is difficult to increase the pixel density of the display apparatus.

### SUMMARY

The disclosure provides a light-emitting device with a reduced assembly area.

The disclosure provides a light-emitting apparatus with increased pixel density.

In an embodiment of the disclosure, a light-emitting device is provided. The light-emitting device includes a carrier, a reflection layer, a common electrode and a first semiconductor stack. The carrier has a light-emitting region, an electrical connection region and a trench, which separates the light-emitting region from the electrical connection region. The reflection layer is disposed on a sidewall of the trench. The common electrode is disposed in the electrical connection region. The first semiconductor stack is disposed in the light-emitting region, wherein a first type semiconductor layer of the first semiconductor stack is electrically connected to the common electrode.

In an embodiment of the disclosure, the carrier is a sapphire substrate.

In an embodiment of the disclosure, a ratio of a depth of the trench to a thickness of the carrier ranges from 10% to 90%.

In an embodiment of the disclosure, an included angle between the sidewall of the trench and a surface of the carrier ranges from 90 degrees to 110 degrees.

In an embodiment of the disclosure, a reflectivity of the reflection layer is not less than 90%.

In an embodiment of the disclosure, the carrier has a plurality of light-emitting regions, and adjacent light-emitting regions are separated by the trench.

In an embodiment of the disclosure, the first type semiconductor layer is electrically connected to the common electrode through the reflection layer.

In an embodiment of the disclosure, the first type semiconductor layer is electrically connected to the common electrode through its side surface or its surface facing away from the carrier.

In an embodiment of the disclosure, the first semiconductor stack further includes a second type semiconductor layer, and the first type semiconductor layer is disposed between the second type semiconductor layer and the carrier.

In an embodiment of the disclosure, the first semiconductor stack further includes a light-emitting layer, and the light-emitting layer is disposed between the first type semiconductor layer and the second type semiconductor layer.

In an embodiment of the disclosure, the light-emitting device further includes a second semiconductor stack, wherein the second semiconductor stack is disposed between the common electrode and the carrier.

In an embodiment of the disclosure, a thickness of the second semiconductor stack is substantially the same as a thickness of the first semiconductor stack.

In an embodiment of the disclosure, the light-emitting device further includes a capping layer, which at least covers a sidewall of the first semiconductor stack.

In an embodiment of the disclosure, the capping layer fills up the trench.

In an embodiment of the disclosure, the reflection layer includes a Bragg reflector layer.

In an embodiment of the disclosure, the light-emitting device further includes an electrically conductive layer, wherein the reflection layer is disposed between the electrically conductive layer and the carrier, and the first type semiconductor layer is electrically connected to the common electrode through the electrically conductive layer.

In an embodiment of the disclosure, a light-emitting apparatus is provided. The light-emitting apparatus includes a circuit substrate, a carrier, a reflection layer, a plurality of first semiconductor stacks and a common electrode. The carrier overlaps the circuit substrate and has an electrical connection region, a plurality of light-emitting regions and a plurality of trenches, wherein the plurality of trenches are disposed respectively between the electrical connection region and the plurality of light-emitting regions as well as between the plurality of light-emitting regions. The reflection layer is disposed on a sidewall of the trench. The plurality of first semiconductor stacks is disposed between the carrier and the circuit substrate and located respectively in the plurality of light-emitting regions. The common electrode is disposed in the electrical connection region and electrically connects first type semiconductor layers of the plurality of first semiconductor stacks to the circuit substrate.

In an embodiment of the disclosure, the common electrode is disposed between the carrier and the circuit substrate.

In an embodiment of the disclosure, the light-emitting apparatus further includes a first connector, which electrically connects the common electrode to the circuit substrate.

In an embodiment of the disclosure, the light-emitting apparatus further includes a second connector, which electrically connects a second type semiconductor layer of one of the plurality of first semiconductor stacks to the circuit substrate.

In an embodiment of the disclosure, the light-emitting apparatus further includes a color conversion layer, wherein the carrier is disposed between the color conversion layer and the circuit substrate.

In an embodiment of the disclosure, the color conversion layer includes a plurality of color conversion structures, which is overlapped with the plurality of first semiconductor stacks respectively.

To make the aforementioned features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a light-emitting device 10 according to an embodiment of the disclosure.

FIG. 1B is a schematic cross-sectional view taken along the section line A-A′ of FIG. 1A.

FIG. 2 is a schematic cross-sectional view of a light-emitting device 20 according to an embodiment of the disclosure.

FIG. 3A to FIG. 3B are schematic cross-sectional views of the step flow of the manufacturing method of the light-emitting device 20 in FIG. 2.

FIG. 4 is a schematic cross-sectional view of a light-emitting device 40 according to an embodiment of the disclosure.

FIG. 5 is a schematic cross-sectional view of a light-emitting device 50 according to an embodiment of the disclosure.

FIG. 6 is a schematic cross-sectional view of a light-emitting device 60 according to an embodiment of the disclosure.

FIG. 7 a schematic cross-sectional view of a light-emitting device 70 according to an embodiment of the disclosure.

FIG. 8A is a schematic top view of a light-emitting device 80 according to an embodiment of the disclosure.

FIG. 8B is a schematic cross-sectional view taken along the section line B-B′ of FIG. 8A.

FIG. 9 is a schematic cross-sectional view of a light-emitting apparatus 100 according to an embodiment of the disclosure.

FIG. 10 is a schematic cross-sectional view of a light-emitting apparatus 200 according to an embodiment of the disclosure.

FIG. 11 shows the luminous intensity simulation results of the light-emitting device 50 as shown in FIG. 5.

### DESCRIPTION OF THE EMBODIMENTS

In the drawings, the thickness of layers, films, panels, regions, etc., is exaggerated for clarity. Throughout the specification, the same reference numerals represent the same elements. It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

It should be understood that although terms such as “first”, “second”, and “third” may be used herein to describe various elements, components, regions, layers, and/or portions, the elements, components, regions, and/or portions are not limited by the terms. The terms are only used to distinguish one element, component, region, layer, or portion from another element, component, region, layer, or portion. Therefore, a first “element”, “component”, “region”, “layer”, or “portion” discussed below may be referred to as a second element, component, region, layer, or portion without departing from the teachings herein.

The terms used herein are only for the purpose of describing specific embodiments and are not limiting. As used herein, unless the content clearly indicates otherwise, the singular forms “a”, “one”, and “the” are intended to include plural forms, including “at least one” or representing “and/or”. As used herein, the term “and/or” includes any and all combinations of one or more of the relevant listed items. It should also be understood that when used in the specification, the terms “containing” and/or “including” designate the presence of the feature, the region, the entirety, the step, the operation, the element, and/or the component, but do not exclude the presence or the addition of one or more other features, regions, entireties, steps, operations, elements, components, and/or combinations thereof.

In addition, relative terms such as “lower” or “bottom” and “upper” or “top” may be used herein to describe the relationship between an element and another element, as shown in the drawings. It should be understood that the relative terms are intended to include different orientations of a device in addition to the orientation shown in the drawings. For example, if the device in a drawing is flipped, an element described as being on the “lower” side of other elements will be oriented on the “upper” side of the other elements. Therefore, the exemplary term “lower” may include the orientations of “lower” and “upper”, depending on the specific orientation of the drawing. Similarly, if the device in a drawing is flipped, an element described as being “under” or “below” other elements will be oriented “above” the other elements. Therefore, the exemplary term “under” or “below” may include the orientations of above and below.

Taking into account the measurement in question and the specific amount of measurement-related error (i.e., the limitations of the measurement system), “about”, “similar”, or “substantially” used in the present specification include the value and the average value within an acceptable deviation range of a specific value confirmed by those having ordinary skill in the art. For example, “about” may represent within one or a plurality of standard deviations of the value, or within ±30%, ±20%, ±10%, or ±5%. Moreover, “about”, “similar”, or “substantially” used in the present specification may include a more acceptable deviation range or standard deviation according to optical properties, etching properties, or other properties, and one standard deviation does not need to apply to all of the properties.

Unless otherwise defined, all terms (including technical and scientific terms) used herein have the same meaning as commonly understood by persons skilled in the art of the disclosure. It will be further understood that terms such as those defined in commonly used dictionaries should be interpreted as having meanings consistent with the meanings in the related art and the context of the disclosure, and will not be interpreted as having idealized or overly formal meanings unless explicitly defined herein.

The exemplary embodiments are described herein with reference to cross-sectional views that are schematic views of idealized embodiments. Therefore, changes in shapes of illustration as a result of, for example, manufacturing technology and/or tolerances may be expected. Therefore, the embodiments described herein should not be interpreted as being limited to the specific shapes of regions as shown herein, but include, for example, shape deviations caused by manufacturing. For example, a region that is shown or described as flat may generally have rough and/or non-linear features. In addition, an acute angle shown may be rounded. Therefore, the regions shown in the drawings are schematic in nature, and the shapes thereof are not intended to show the precise shapes of the regions and are not intended to limit the scope of the claims.

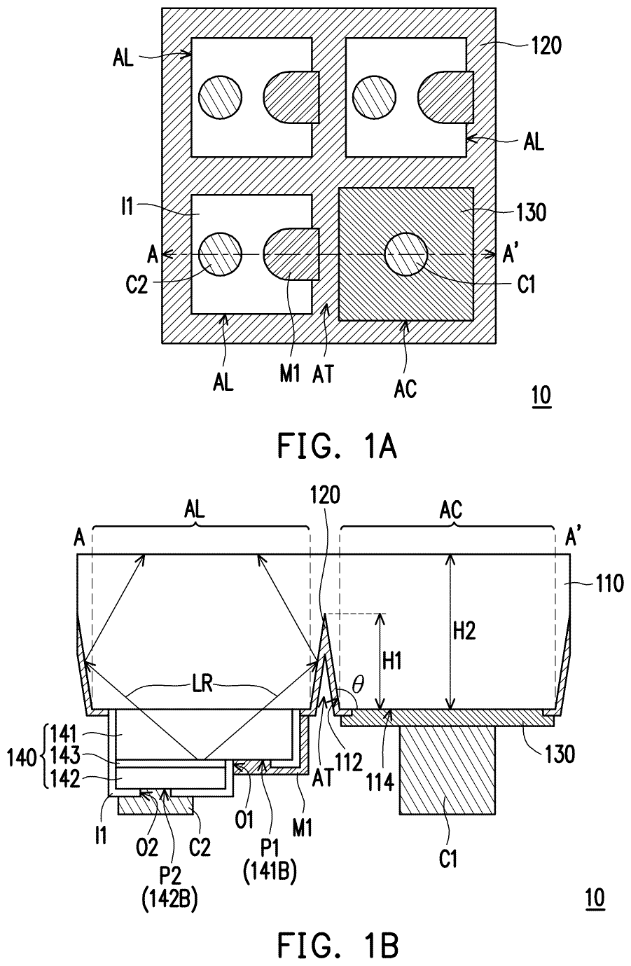

FIG. 1A is a schematic top view of a light-emitting device 10 according to an embodiment of the disclosure. FIG. 1B is a schematic cross-sectional view taken along the section line A-A′ of FIG. 1A. In order to make the illustration of the drawing more concise, FIG. 1A schematically depicts a reflection layer 120, a common electrode 130, a light-emitting region AL, an electrical connection region AC and a trench AT, and omits other elements.

Please referring to FIG. 1A and FIG. 1B, the light-emitting device 10 includes: a carrier 110 having a light-emitting region AL, an electrical connection region AC and a trench AT, which separates the light-emitting region AL from the electrical connection region AC; a reflection layer 120 disposed on a sidewall 112 of the trench AT; a common electrode 130 disposed in the electrical connection region AC; and a first semiconductor stack 140 disposed in the light-emitting region AL, wherein a first type semiconductor layer 141 of the first semiconductor stack 140 is electrically connected to the common electrode 130.

In the light-emitting device 10 according to an embodiment of the disclosure, by the disposition of the trench AT in the carrier 110 and the reflection layer 120 in the trench AT for light collection, no isolation structure is needed between the light-emitting devices 10 to avoid light mixing. In addition, by connecting the first type semiconductor layers 141 to the common electrode 130 in parallel, the number of pads for electrically connecting the external circuits to the light-emitting devices 10 can be reduced, thereby reducing the assembly area of the light-emitting devices 10.

Hereinafter, the implementation manner of each element of the light-emitting device 10 will be illustrated successively with reference to FIG. 1A and FIG. 1B, but the disclosure is not limited thereto.

Specifically, the carrier 110 of the light-emitting device 10 may be a growth substrate of the light-emitting device 10, such as a sapphire substrate, but the disclosure is not limited thereto. In some embodiments, the carrier 110 of the light-emitting device 10 is a rigid substrate, such as a glass substrate, a quartz substrate or a ceramic substrate, and the light-emitting device 10 may be transferred from the growth substrate to the carrier 110. For example, the light-emitting device 10 may be transferred to the carrier 110 through the mass transfer process. In some embodiments, the light-emitting device 10 can further be fixed on a surface of the carrier 110 through an adhesive material (not shown).

The carrier 110 may have the light-emitting region AL, the electrical connection region AC and the trench AT, and the trench AT may be located between the light-emitting region AL and the electrical connection region AC to separate the light-emitting region AL from the electrical connection region AC. In some embodiments, the carrier 110 has a plurality of light-emitting regions AL, and the trench AT separates two adjacent light-emitting regions AL and the adjacent light-emitting region AL and electrical connection region AC. In some embodiments, the light-emitting region AL and the electrical connection region AC are arranged in an array. In some embodiments, the trench AT may have a grid profile, and the light-emitting regions AL and the electrical connection region AC may be located in the grid cells of the grid structure of the trench AT respectively. In some embodiment, each light-emitting region AL forms a sub-pixel unit, and three light-emitting regions AL and one electrical connection region AC may constitute a pixel unit. In some embodiments, the first type semiconductor layers 141 in the three light-emitting regions AL are all connected to the common electrode 130 in the one electrical connection region AC. In some embodiments, the three light-emitting regions AL and the one electrical connection region AC are arranged in a 2×2 array. In some embodiments, the first type semiconductor layers 141 in four, five, six or more light-emitting regions AL are all connected to the common electrode 130 in the electrical connection region AC.

The trench AT may have a triangular cross-sectional profile without a planar bottom surface away from a surface 114 of the carrier 110, but the disclosure is not limited thereto. For example, a narrow end of the V-shaped cross-section of the trench AT may be the end away from the surface 114 of the carrier 110. In consideration of the support property of the carrier 110, a ratio of a depth H1 of the trench AT to a thickness H2 of the carrier 110 may not be greater than 95%. In some embodiments, the ratio of the depth H1 of the trench AT to the thickness H2 of the carrier 110 ranges from 10% to 90%. For example, the ratio of the depth H1 of the trench AT to the thickness H2 of the carrier 110 is about 20%, 50% or 80%. In some embodiments, an included angle θ between the sidewall 112 of the trench AT and the surface 114 of the carrier 110 is greater than 90 degrees, such as 95 degrees, 100 degrees or 105 degrees.

The reflection layer 120 may at least cover the sidewall 112 of the trench AT. As a result, the reflection layer 120 can reflect light LR emitted by the light-emitting layer 143, such that the output of light LR is more concentrated, which prevents light LR from entering other light-emitting regions AL, thereby avoiding light mixing. In some embodiments, the reflection layer 120 may fill up the trench AT. The material of the reflection layer 120 may be highly reflective. In some embodiments, a reflectivity of the reflection layer 120 is not less than 90%. For example, the reflectivity of the reflection layer 120 is about 92%, 95% or 98%. In some embodiments, the reflection layer 120 may include silver (Ag), aluminum (Al) or a combination thereof, but the disclosure is not limited thereto.

The common electrode 130 of the light-emitting device 10 may be electrically connected to the first semiconductor stack 140 disposed in the light-emitting region AL. In some embodiments, the common electrode 130 is electrically connected to the light-emitting region AL through the reflection layer 120. In some embodiments, the common electrode 130 is electrically connected with the reflection layer 120. In some embodiments, the common electrode 130 physically touches the reflection layer 120. The material of the common electrode 130 may include titanium, aluminum, nickel, gold or a combination thereof, but the disclosure is not limited thereto.

In some embodiments, the light-emitting device 10 further includes a connector C1. The connector C1 is electrically connected to the common electrode 130, and the common electrode 130 can be electrically connected to the components external the light-emitting device 10 through the connector C1. In some embodiments, the connector C1 is disposed on a surface of the common electrode 130 far away from the carrier 110. In some embodiments, the material of the connector C1 includes a metal, an alloy, a nitride of a metal material, an oxide of a metal material, an oxynitride of a metal material, graphene or a combination thereof.

The first semiconductor stack 140 of the light-emitting device 10 may be disposed on the surface 114 of the carrier 110 and may include a first type semiconductor layer 141, a second type semiconductor layer 142 and a light-emitting layer 143, wherein the first type semiconductor layer 141 may be disposed between the second type semiconductor layer 142 and the carrier 110, and the light-emitting layer 143 may be disposed between the first type semiconductor layer 141 and the second type semiconductor layer 142.

The first type semiconductor layer 141 may comprise an N-type doped semiconductor material, such as an N-type II-VI group material (for example, zinc selenide (ZnSe)), an N-type III-V group nitride material (for example, gallium nitride (GaN), aluminum nitride (AlN), indium nitride (InN), indium gallium nitride (InGaN), aluminum gallium nitride (AlGaN) or aluminum indium gallium nitride (AlInGaN)) or a stack thereof. The second type semiconductor layer 142 may include a P-type doped semiconductor material, such as a P-type II-VI group material, a P-type III-V group nitride material or a stack thereof. The light-emitting layer 143 may include a multiple quantum well (MQW) structure, which may include multiple layers of the II-VI group material and multiple layers of the III-V group nitride material that are stacked alternately, but the disclosure is not limited thereto. In some embodiments, the light-emitting device 10 is a Micro-light-emitting diode (Micro-LED).

In some embodiments, the first type semiconductor layer 141 of the first semiconductor stack 140 may electrically connect the common electrode 130 through the reflection layer 120. For example, the light-emitting device 10 further includes an electrically conductive layer M1, a surface 141B of the first type semiconductor layer 141 away from the carrier 110 partially overlaps the second type semiconductor layer 142 and the light-emitting layer 143, and a portion P1 of the surface 141B does not overlap the second type semiconductor layer 142 and the light-emitting layer 143 and may electrically connect the reflection layer 120 through the electrically conductive layer M1, thereby electrically connecting the common electrode 130. In some embodiments, the electrically conductive layer M1 is located in the light-emitting region AL, and the portion P1 of the surface 141B of the first type semiconductor layer 141 connects or physically contacts the electrically conductive layer M1. In some embodiments, the electrically conductive layer M1 connects or physically contacts the reflection layer 120. In some embodiments, the electrically conductive layer M1 may also be filled in the trench AT and cover the entire reflection layer 120.

In some embodiments, the light-emitting device 10 further includes an insulating layer I1. The insulating layer I1 may cover all surfaces of the first semiconductor stack 140 except the surface of the first semiconductor stack 140 facing the carrier 110. Further, the insulating layer I1 may have an opening O1 and an opening O2, wherein the opening O1 may expose the first type semiconductor layer 141, and the opening O2 may expose the second type semiconductor layer 142. In some embodiments, the openings O1 and O2 of the insulating layer I1 of the light-emitting device 10 are located on the same side of the first semiconductor stack 140. In some embodiments, the opening O1 may expose the portion P1 of the surface 141B of the first type semiconductor layer 141 away from the carrier 110, and the opening O2 may expose a portion P2 of a surface 142B of the second type semiconductor layer 142 away from the carrier 110.

In some embodiments, the light-emitting device 10 further includes a connector C2, and the connector C2 is disposed on the surface 142B of the second type semiconductor layer 142 such that the second type semiconductor layer 142 can electrically connect the components external the light-emit element 10 through the connector C2. In some embodiments, the connector C2 is disposed in the opening O2 of the insulating layer I1, and the connector C2 connects the portion P2 of the surface 142B of the second type semiconductor layer 142 through the opening O2. In some embodiments, the material of the connector C2 includes a metal, an alloy, a nitride of a metal material, an oxide of a metal material, an oxynitride of a metal material, graphene or a combination thereof.

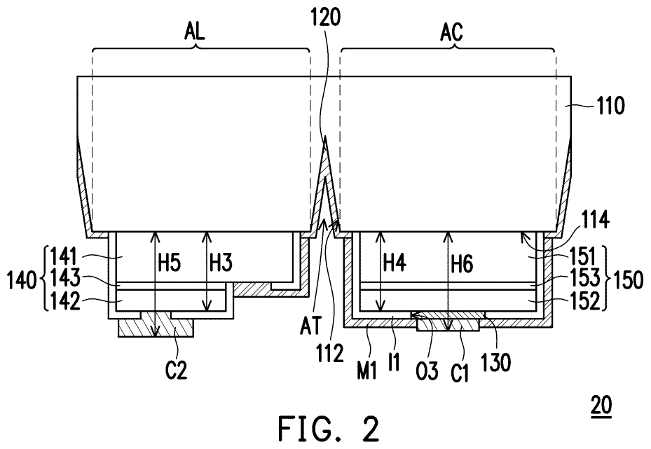

In the subsequent paragraphs, other embodiments of the disclosure are further illustrated with reference to FIG. 2 to FIG. 10. Reference numerals and relevant content of the elements of the embodiments of FIG. 1A to FIG. 1B are used in the illustration, the same reference numerals are used to denote the same or similar elements, and the description of the same technical content is omitted. For the omitted description, refer to the embodiments of FIG. 1A to FIG. 1B, which is not repeated hereinafter.

FIG. 2 is a schematic cross-sectional view of a light-emitting device 20 according to an embodiment of the disclosure. The light-emitting device 20 includes the carrier 110, the reflection layer 120, the common electrode 130, the first semiconductor stack 140, the connector C1, the connector C2, the insulating layer I1 and the electrically conductive layer M1, and has the light-emitting region AL, the electrical connection region AC and the trench AT. Compared with the light-emitting device 10 as shown in FIG. 1A to FIG. 1B, the light-emitting device 20 shown in FIG. 2A to FIG. 2B is mainly different in that the light-emitting device 20 further includes a second semiconductor stack 150 disposed between the common electrode 130 and the carrier 110.

In some embodiments, the second semiconductor stack 150 further includes a first type semiconductor layer 151, a second type semiconductor layer 152 and a light-emitting layer 153, wherein the first type semiconductor layer 151 may be located between the second type semiconductor layer 152 and the carrier 110, and the light-emitting layer 153 may be located between the first type semiconductor layer 151 and the second type semiconductor layer 152. In some embodiments, the material of the first type semiconductor layer 151 may be substantially the same as that of the first type semiconductor layer 141. In some embodiments, the material of the second type semiconductor layer 152 may be substantially the same as that of the second type semiconductor layer 142. In some embodiments, the material of the light-emitting layer 153 may be substantially the same as that of the light-emitting layer 143. In some embodiments, a thickness H4 of the second semiconductor stack 150 is substantially the same as a thickness H3 of the first semiconductor stack 140.

In some embodiments, the insulating layer I1 of the light-emitting device 20 further covers all surfaces of the second semiconductor stack 150 except the surface of the second semiconductor stack 150 facing the carrier 110 and has an opening O3. In some embodiment, the common electrode 130 is disposed in the opening O3. In some embodiments, the common electrode 130 is located between the second semiconductor stack 150 and the connector C1. In some embodiments, the total thickness H5 of the first semiconductor stack 140 and the connector C2 is substantially equal to the total thickness H6 of the second semiconductor stack 150, the common electrode 130 and the connector C1.

In some embodiments, the electrically conductive layer M1 of the light-emitting device 20 is further located in the electrical connection region AC and covers the second semiconductor stack 150, and the electrically conductive layer M1 electrically connects the reflection layer 120 with the common electrode 130. In some embodiments, a portion of the electrically conductive layer M1 located in the electrical connection region AC connects or physically contacts the reflection layer 120. In some embodiments, the portion of the electrically conductive layer M1 located in the electrical connection region AC connects or physically contacts the common electrode 130. In other words, the first type semiconductor layer 141 of the first semiconductor stack 140 can electrically connect the common electrode 130 through the portion of the electrically conductive layer M1 located in the light-emitting region AL, the reflection layer 120 and the portion of the electrically conductive layer M1 located in the electrical connection region AC sequentially.

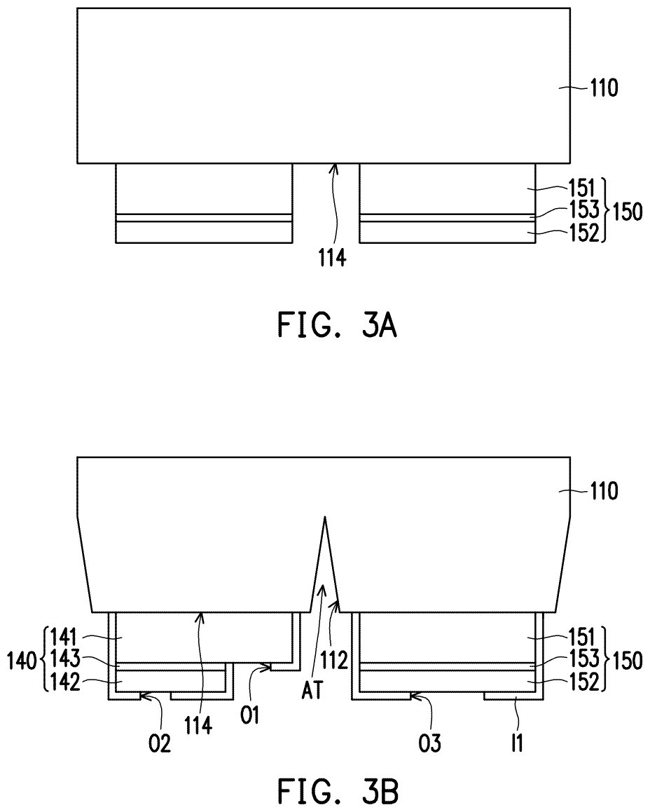

FIG. 3A to FIG. 3B are schematic cross-sectional views of the step flow of the manufacturing method of the light-emitting device 20 in FIG. 2. Hereinafter, a manufacturing method of the light-emitting device 20 will be described with reference to FIG. 3A to FIG. 3B and FIG. 2.

With reference to FIG. 3A, in some embodiments, a plurality of second semiconductor stacks 150 are formed on the surface 114 of the carrier 110. For example, a continuous first type semiconductor layer, a continuous light-emitting layer and a continuous second type semiconductor layer may be formed sequentially on the surface 114 of the carrier 110, then a patterning process is carried out to form a plurality of second semiconductor stack 150 that are separated from each other, and the second semiconductor stack 150 includes the first type semiconductor layer 151, the light-emitting layer 153 and the second type semiconductor layer 152 that are stacked sequentially.

With reference to FIG. 3B, next, a portion of the second semiconductor stacks 150 may be subject to a patterning process to form the first semiconductor stack 140. For example, the second type semiconductor layer 152 and the light-emitting layer 153 of the second semiconductor stack 150 may be patterned to form the second type semiconductor layer 142 and the light-emitting layer 143 respectively, and the first type semiconductor layer 141 may has a pattern that is substantially the same as that of the first type semiconductor layer 151.

Next, the insulating layer I1 may be formed around both the first semiconductor stack 140 and the second semiconductor stack 150. In some embodiment, the insulating layer I1 covers all the surfaces of the first semiconductor stack 140 and second semiconductor stack 150 except the surfaces of the first semiconductor stack 140 and second semiconductor stack 150 that face the carrier 110, and has the openings O1, O2 and O3, wherein the opening O1 overlaps and exposes the first type semiconductor layer 141, the opening O2 overlaps and exposes the second type semiconductor layer 142, and the opening O3 overlaps and exposes the second type semiconductor layer 152.

Next, a plurality of trenches AT may be formed on the surface 114 of the carrier 110 by using, for example, an etching process, and the trenches AT may separate the first semiconductor stack 140 from the second semiconductor stack 150 and separate the second semiconductor stacks 150 from each other. In some embodiments, the plurality of trenches AT may communicate with each other.

With reference to FIG. 2, next, the reflection layer 120, the common electrode 130 and the electrically conductive layer M1 may be formed using, for example, the physical vapor deposition process. For example, the reflection layer 120 may be formed on the surface of the sidewall 112 of the trench AT. In addition, the common electrode 130 may be formed in the opening O3 of the insulating layer I1. Next, in the light-emitting region AL, the electrically conductive layer M1 may be formed on a portion of the insulating layer I1 that covers a sidewall of the first type semiconductor layer 141 facing the second semiconductor stack 150, and the electrically conductive layer M1 further extends into the opening O1 of the insulating layer I1 such that the electrically conductive layer M1 electrically connects the first type semiconductor layer 141 with the reflection layer 120. Simultaneously, in the electrical connection region AC, the electrically conductive layer M1 may be formed on portions of the insulating layer I1 that cover the sidewalls of the second semiconductor stack 150, and the electrically conductive layer M1 further extends to the common electrode 130 so that the electrically conductive layer M1 electrically connects the reflection layer 120 with the common electrode 130. Next, the connector C1 may be formed on the common electrode 130 and the connector C2 may be formed in the opening O2 of the insulating layer I1 to complete the fabrication of the light-emitting device 20.

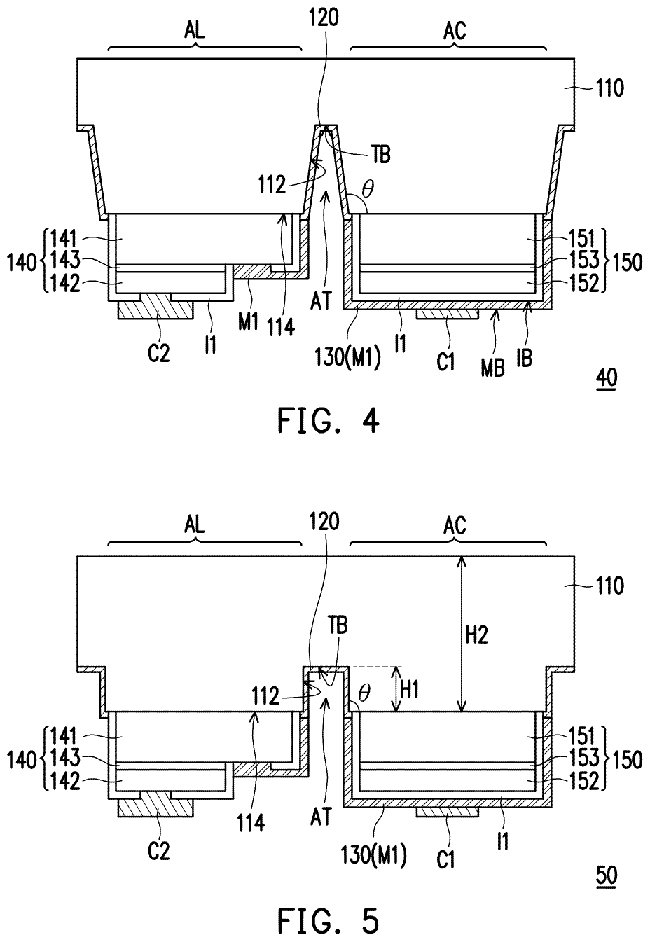

FIG. 4 is a schematic cross-sectional view of a light-emitting device 40 according to an embodiment of the disclosure. The light-emitting device 40 includes the carrier 110, the reflection layer 120, the common electrode 130, the first semiconductor stack 140, the second semiconductor stack 150, the connector C1, the connector C2, the insulating layer I1 and the electrically conductive layer M1, and has the light-emitting region AL, the electrical connection region AC and the trench AT. Compared with the light-emitting device 20 as shown in FIG. 2, the light-emitting device 40 shown in FIG. 4 is mainly different in that the trench AT of the light-emitting device 40 has a flat bottom surface TB, and the included angle θ between the sidewall 112 of the trench AT and the surface 114 of the carrier 110 is greater than 90 degrees and less than 110 degrees so that the opening dimension of the trench AT in the plane of the surface 114 is greater than the dimension of the bottom surface TB of the trench AT and the trench AT has a trapezoidal cross-sectional profile.

In some embodiments, the insulating layer I1 may not have the opening O3, and the insulating layer I1 completely covers all surfaces of the second semiconductor stack 150 except the surface of the second semiconductor stack 150 facing the carrier 110. In some embodiments, in the electrical connection region AC, the electrically conductive layer M1 completely covers the insulating layer I1 and connects a portion of the reflection layer 120 that surrounds the second semiconductor stack 150. In some embodiments, the common electrode 130 is a portion of the electrically conductive layer M1. In some embodiments, the common electrode 130 is the portion of the electrically conductive layer M1 that is disposed on a surface IB of the insulating layer I1 away from the carrier 110. In some embodiments, the connector C1 is disposed on a surface MB of the electrically conductive layer M1 away from the carrier 110.

FIG. 5 is a schematic cross-sectional view of a light-emitting device 50 according to an embodiment of the disclosure. The light-emitting device 50 includes the carrier 110, the reflection layer 120, the common electrode 130, the first semiconductor stack 140, the second semiconductor stack 150, the connector C1, the connector C2, the insulating layer I1 and the electrically conductive layer M1, and has the light-emitting region AL, the electrical connection region AC and the trench AT. Compared with the light-emitting device 40 as shown in FIG. 4, the light-emitting device 50 shown in FIG. 5 is mainly different in that the trench AT of the light-emitting device 50 has a planar bottom surface TB, and the included angle θ between the sidewall 112 of the trench AT and the surface 114 of the carrier 110 is about 90 degrees, so that the opening dimension of the trench AT in the plane of the surface 114 is substantially equal to the dimension of the bottom surface TB of the trench AT and the trench AT has a rectangular cross-sectional profile.

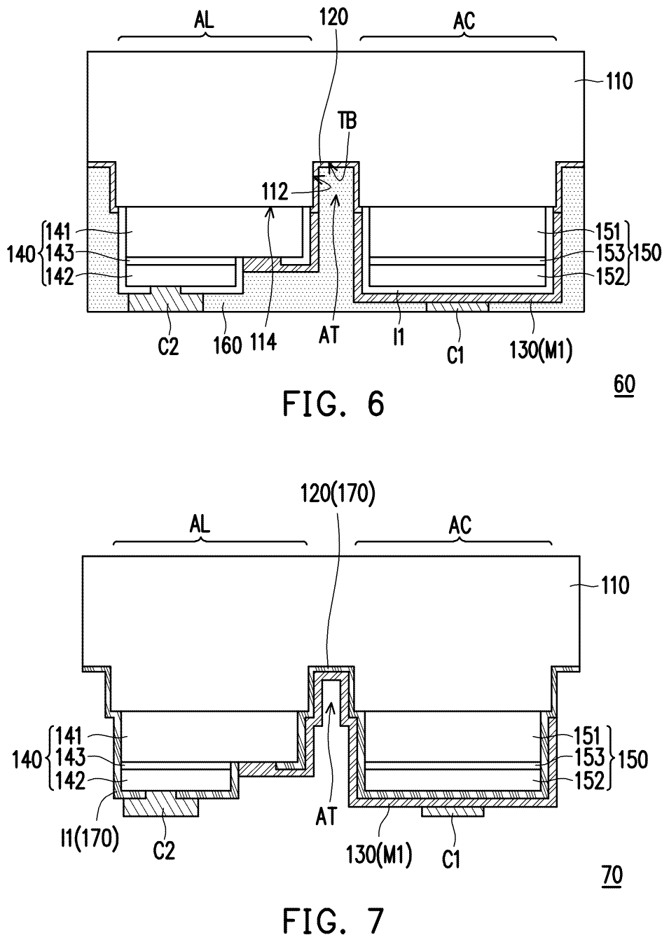

FIG. 6 is a schematic cross-sectional view of a light-emitting device 60 according to an embodiment of the disclosure. The light-emitting device 60 includes the carrier 110, the reflection layer 120, the common electrode 130, the first semiconductor stack 140, the second semiconductor stack 150, the connector C1, the connector C2, the insulating layer I1 and the electrically conductive layer M1, and has the light-emitting region AL, the electrical connection region AC and the trench AT. Compared with the light-emitting device 50 as shown in FIG. 5, the light-emitting device 60 shown in FIG. 6 is mainly different in that the light-emitting device 60 further includes a capping layer 160, and the capping layer 160 may at least cover the sidewall of the first semiconductor stacks 140 to avoid light leakage. In some embodiments, the capping layer 160 fills up the trench AT and covers all the surfaces of the first semiconductor stack 140 and the second semiconductor stack 150 except the surfaces of the first semiconductor stack 140 and the second semiconductor stack 150 facing the carrier 110. In addition, the capping layer 160 may be flush with the connectors C1 and C2 but not cover the connectors C1 and C2 so that the entire appearance of the light-emitting device 60 is relatively flat and compact.

In some embodiments, the material of the capping layer 160 may comprise a non-conductive light-absorbing or light-shielding material, such as the black resin and other materials with low light transmittance. In some embodiments, the material of the capping layer 160 may comprise an organic isolation material, such as a photoresist material, a curable resin material or other suitable materials, and the disclosure is not limited thereto.

FIG. 7 a schematic cross-sectional view of a light-emitting device 70 according to an embodiment of the disclosure. The light-emitting device 70 includes the carrier 110, the reflection layer 120, the common electrode 130, the first semiconductor stack 140, the second semiconductor stack 150, the connector C1, the connector C2, the insulating layer I1 and the electrically conductive layer M1, and has the light-emitting region AL, the electrical connection region AC and the trench AT. Compared with the light-emitting device 50 as shown in FIG. 5, the light-emitting device 70 shown in FIG. 7 is mainly different in that the reflection layer 120 of the light-emitting device 70 includes a portion of a Bragg reflection layer 170, which makes the light-emitting device 70 have angle selectivity with respect to its light output.

For example, the Bragg reflection layer 170 may include plural layers of low refractive index and plural layers of high refractive index that overlap alternately. In some embodiments, the layer of low refractive index has a refractive index less than 1.7, such as 1.5 or 1.6, and the layer of high refractive index has a refractive index greater than 1.7, such as 1.8 or 2.1, but the disclosure is not limited thereto. In some embodiments, the insulating layer I1 of the light-emitting device 70 includes another portion of the Bragg reflection layer 170, and the reflection layer 120 and the insulating layer I1 belong to the same layer. In certain embodiments, the Bragg reflection layer 170 of the light-emitting device 70 is composed of the reflection layer 120 and the insulating layer I1.

In some embodiments, the electrically conductive layer M1 of the light-emitting device 70 further covers the reflection layer 120 between the light-emitting region AL and the electrical connection region AC such that the reflection layer 120 is disposed between the electrically conductive layer M1 and the carrier 110, and the first type semiconductor layer 141 can be electrically connected to the common electrode 130 just through the electrically conductive layer M1.

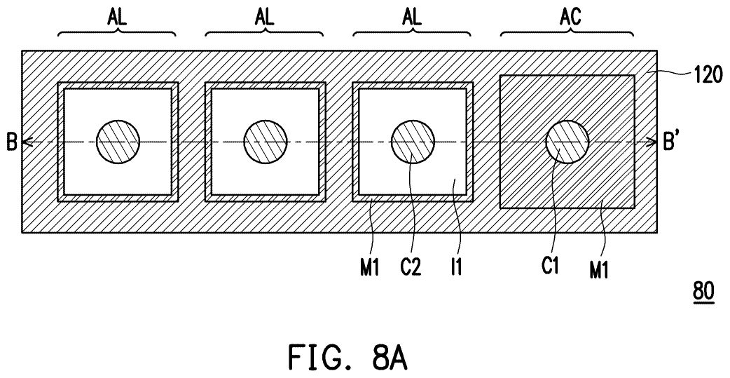

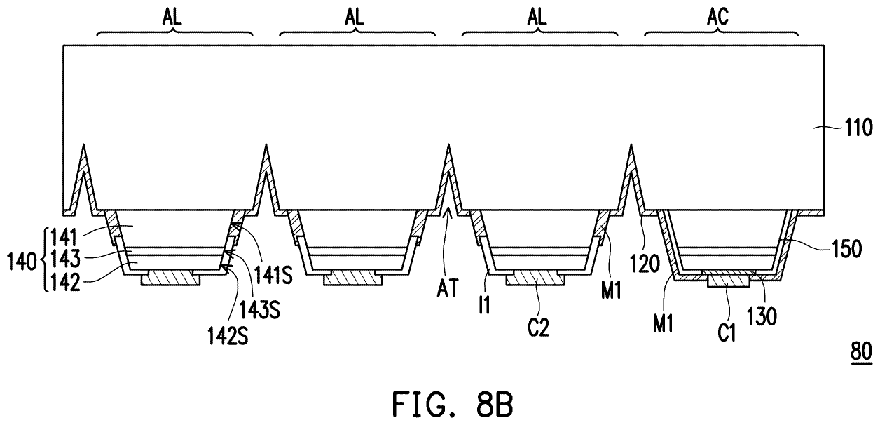

FIG. 8A is a schematic top view of a light-emitting device 80 according to an embodiment of the disclosure. FIG. 8B is a schematic cross-sectional view taken along the section line B-B′ of FIG. 8A. The light-emitting device 80 includes the carrier 110, the reflection layer 120, the common electrode 130, the first semiconductor stack 140, the second semiconductor stack 150, the connector C1, the connector C2, the insulating layer I1 and the electrically conductive layer M1, and has the light-emitting region AL, the electrical connection region AC and the trench AT. Compared with the light-emitting device 20 as shown in FIG. 2, the light-emitting device 80 shown in FIG. 8A to FIG. 8B is mainly different in that the first type semiconductor layer 141 of the first semiconductor stack 140 of the light-emitting device 80 is electrically connected to the common electrode 130 through its side surface 141S.

For example, in the light-emitting region AL, the insulating layer I1 of the light-emitting device 80 at least covers the side surface 142S of the second type semiconductor layer 142 and the side surface 143S of the light-emitting layer 143. The insulating layer I1 does not cover a portion of the side surface 141S of the first type semiconductor layer 141, or the insulating layer I1 at least exposes a portion of the side surface 141S. The electrically conductive layer M1 covers the portion of the side surface 141S of the first type semiconductor layer 141 that is not covered by the insulating layer I1 and connects the reflection layer 120 in the trench AT. In some embodiments, the light-emitting device 80 is a vertical Micro-LED. In some embodiments, the light-emitting device 80 may include three light-emitting regions ALs and one electrical connection region AC, and the three light-emitting regions ALs and the one electrical connection region AC are arranged in a 1×4 array.

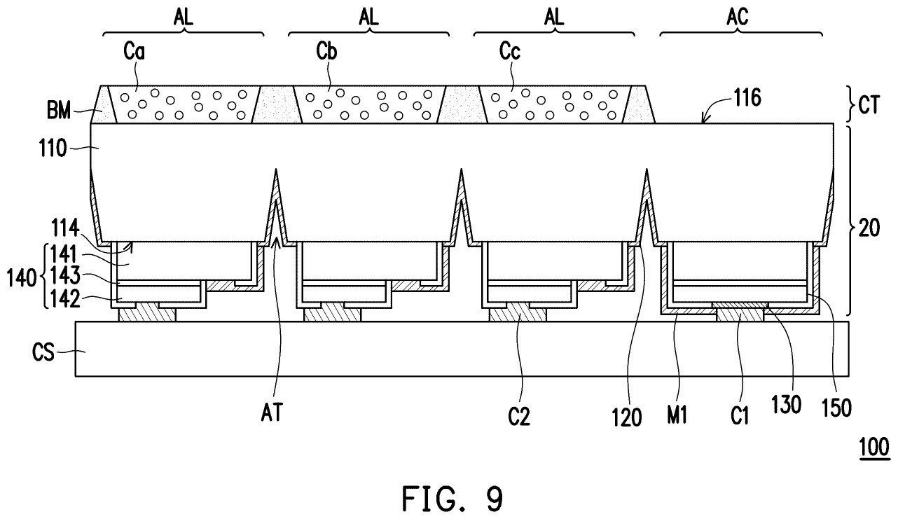

FIG. 9 is a schematic cross-sectional view of a light-emitting apparatus 100 according to an embodiment of the disclosure. The light-emitting apparatus 100 may include a circuit substrate CS and the light-emitting device 20, and the connectors C1 and C2 of the light-emitting device 20 are electrically connected to the circuit substrate CS. In some embodiments, any one of the light-emitting devices 10, 40, 50, 60, 70 and 80 described above can be used to replace the light-emitting device 20 in the light-emitting apparatus 100. In other words, the light-emitting apparatus 100 may include the circuit substrate CS and any one of the light-emitting devices 10, 40, 50, 60, 70 and 80 described above.

In some embodiments, the circuit substrate CS may include a stack of a base plate and a driving circuit layer. The base plate of the circuit substrate CS may be a transparent plate or a non-transparent plate, and its material may be quartz, glass, polymer or other appropriate materials, but the disclosure is not limited thereto. The driving circuit layer may include components or signal lines required by the light-emitting apparatus 100. For example, when the light-emitting apparatus 100 is used as a display device, the driving circuit layer may include the components or signal lines required by the display device, such as the driver, the switch, the storage capacitor, the power line, the driving signal line, the time sequence signal line, the current compensation line, the detection signal line, etc.

In some embodiments, the carrier 110 of the light-emitting device 20 overlaps the circuit substrate CS. In some embodiments, a plurality of first semiconductor stacks 140 of the light-emitting device 20 are respectively disposed in a plurality of light-emitting regions AL and located between the carrier 110 and the circuit substrate CS. In some embodiments, the common electrode 130 of the light-emitting device 20 is located in the electrical connection region AC between the carrier 110 and the circuit substrate CS. In some embodiments, the light-emitting apparatus 100 has a plurality of light-emitting regions AL and a plurality of electrical connection regions AC.

In some embodiments, the connector C1 of the light-emitting device 20 electrically connects the common electrode 130 with the circuit substrate CS. In some embodiments, the circuit substrate CS is electrically connected to the first type semiconductor layers 141 of the plurality of first semiconductor stacks 140 through the connector C1, the common electrode 130, the electrically conductive layer M1 and the reflection layer 120. Since the reflection layer 120 can concentrate the light emitted by the first semiconductor stack 140 of each light-emitting region AL, it need not configure the isolation structure between the plurality of light-emitting regions AL to avoid light mixing, thereby increasing the pixel density (or pixels per inch (PPI)) of the light-emitting apparatus 100 and reducing the overall thickness of the light-emitting apparatus 100. In addition, the circuit substrate CS can electrically connect the first type semiconductor layers 141 of the plurality of first semiconductor stacks 140 just through the connector C1, so the number of the bonding pads of the circuit substrate CS and the assembly area of the light-emitting device 20 can be reduced simultaneously, thereby increasing the pixel density (or PPI) of the light-emitting apparatus 100.

In some embodiments, the connector C2 of the light-emitting device 20 electrically connects the second type semiconductor layer 142 of the first semiconductor stack 140 with the circuit substrate CS. In some embodiments, the second semiconductor stack 150 of the light-emitting device 20 is located between the circuit substrate CS and the carrier 110. Since the circuit connection between the connectors C1 and C2 and the circuit substrate CS can be completed in the same step, the production procedure of the light-emitting apparatus 100 can also be simplified.

In some embodiments, the light-emitting apparatus 100 further includes a color conversion layer CT, which can be disposed on a surface 116 of the carrier 110 so that the carrier 110 is located between the color conversion layer CT and the circuit substrate CS. The surface 116 of the carrier 110 may be opposite to the surface 114, and the surface 116 may be flat. In some embodiments, the color conversion layer CT includes color conversion structures Ca, Cb and Cc, the color conversion structures Ca, Cb and Cc are disposed in a plurality of light-emitting regions AL respectively, and each of the color conversion structures Ca, Cb and Cc overlaps a corresponding first semiconductor stack 140 to convert the color of light emitted by the corresponding first semiconductor stack 140 into the desired color. The material of the color conversion structures Ca, Cb and Cc may include quantum dots (QD), fluorescent materials or wavelength conversion materials of similar properties, such as silicates, silicon nitrides, sulfides, quantum dots, garnets or the like.

For example, the light-emitting layer 143 of the first semiconductor stack 140 may emit blue light, and the color conversion structures Ca and Cb may respectively include the red filter pattern and the green filter pattern, so as to convert the blue light emitted by the corresponding first semiconductor stacks 140 into red and green light respectively. In some embodiments, the blue light emitted by the first semiconductor stack 140 corresponding to the color conversion structure Cc does not need color conversion, and the color conversion structure Cc may include an optical material with high light transmittance. In some embodiments, the refractive index of the optical material of the color conversion structure Cc is between the refractive index of the carrier 110 and the refractive index of air, so as to facilitate light extraction. As a result, those first semiconductor stacks 140 corresponding to the color conversion structures Ca, Cb and Cc respectively may constitute one full-color pixel.

In some embodiments, the color conversion layer CT further includes a plurality of light-shielding structures BM, and the plurality of light-shielding structure BM is respectively located between the color conversion structures Ca, Cb and Cc to avoid light mixing. In some embodiments, each light-shielding structure BM may overlap a corresponding trench AT.

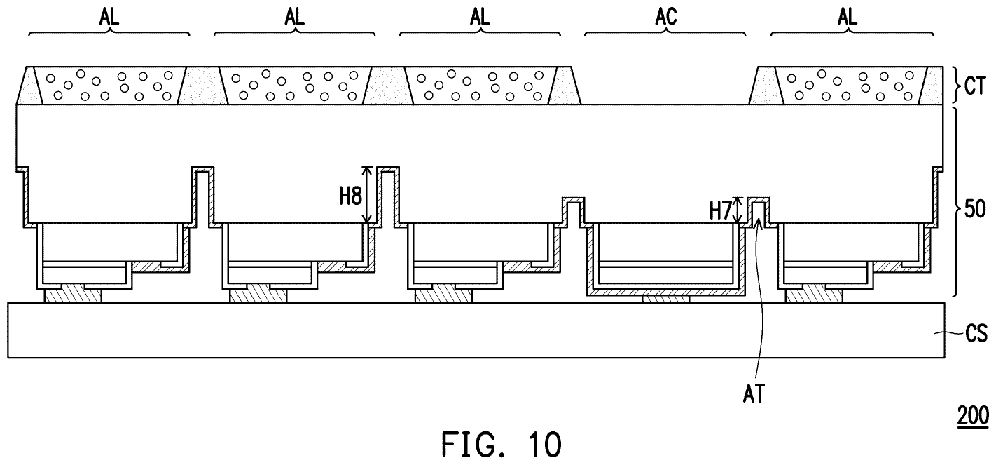

FIG. 10 is a schematic cross-sectional view of a light-emitting apparatus 200 according to an embodiment of the disclosure. The light-emitting apparatus 200 may include the circuit substrate CS, the light-emitting device 50 described above and the color conversion layer CT, and the light-emitting apparatus 200 may have a plurality of light-emitting regions AL and a plurality of electrical connection regions AC. Compared with the light-emitting apparatus 100 as shown in FIG. 9, the light-emitting apparatus 200 shown in FIG. 10 is mainly different in that the light-emitting device 50 substitutes for the light-emitting device 20 in the light-emitting apparatus 200, and the trenches AT of the light-emitting apparatus 200 may have various depths.

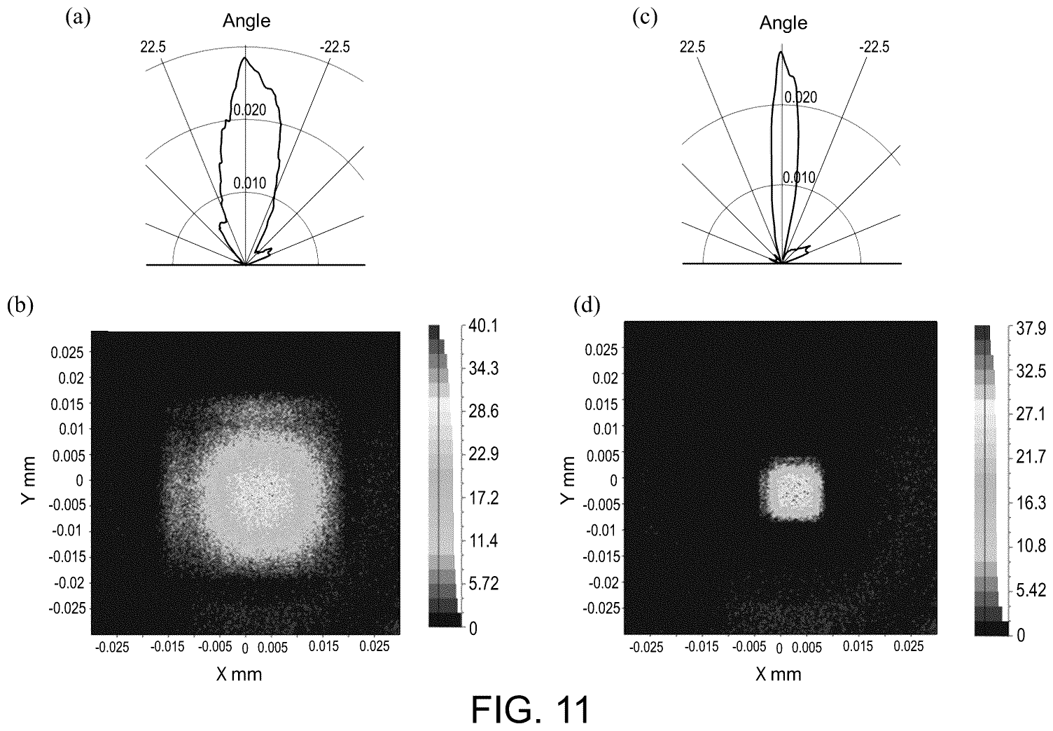

FIG. 11 shows the luminous intensity simulation results of the light-emitting device 50 as shown in FIG. 5. In FIG. 11. figure (a) and figure (b) show the luminous intensity distribution in which the ratio of the depth H1 of the trench AT to the thickness H2 of the carrier 110 in the light-emitting device 50 is about 20%, and figure (c) and figure (d) show the luminous intensity distribution in which the ratio of the depth H1 of the trench AT to the thickness H2 of the carrier 110 in the light-emitting device 50 is about 50%. From figure (a) to figure (d) of FIG. 11, it can be seen that as the ratio of the depth H1 of the trench AT to the thickness H2 of the carrier 110 increases, the range of viewing angle of the light-emitting device 50 becomes narrow. Therefore, it is feasible to provide a display effect of wide viewing angle or narrow viewing angle in individual area by using an appropriate trench depth.

With reference to FIG. 10, in some embodiments, the trench AT adjacent to the electrical connection region AC may have a depth H7, the trench AT located between the light-emitting regions AL may have a depth H8, and the depth H7 is less than the depth H8. As a result, the light-emitting region AL adjacent to the electrical connection region AC can provide a wide viewing angle scope to avoid the dark spot formed by the electrical connection region AC, and the light-emitting region AL not adjacent to the electrical connection region AC can provide a narrow viewing angle scope to avoid light mixing. In some embodiments, the trench AT with a specific depth may be configured in the selected region to provide the wide or narrow viewing angle display effect, depending on the needs of the application.

To sum up, the light-emitting device of the disclosure can reduce the number of pads for electrically connecting the external circuit through the parallel connections between the first type semiconductor layers and the common electrode, thereby reducing the assembly area of the light-emitting device. Further, the light-emitting device of the disclosure collects light by disposing the reflection layer in the trench of the carrier, so no isolation structure is needed for avoiding light mixing. In addition, the light-emitting apparatus uses the common electrode to electrically connect multiple first-type semiconductor layers with the circuit substrate, which can reduce the number of pads of the circuit substrate, thereby increasing the pixel density or PPI. Furthermore, the light-emitting apparatus of the disclosure collects light through the reflective layer arranged in the carrier, so no isolation structure is required, the pixel density can be increased and the overall thickness of the light-emitting apparatus can be reduced. Moreover, the color conversion structures can be directly disposed on the flat surface of the carrier, and the circuit connection between the light-emitting devices and the circuit substrate can be completed in the same step, so as to simplify the production procedure of the light-emitting apparatus.

Although the disclosure has been described in detail with reference to the above embodiments, the embodiments are not intended to limit the disclosure. Those skilled in the art should understand that it is possible to make changes and modifications without departing from the spirit and scope of the disclosure. Therefore, the protection scope of the disclosure shall be defined by the appended claims.

What is claimed is:

1. A light-emitting device, comprising:
a carrier having a light-emitting region, an electrical connection region and a trench, which separates the light-emitting region from the electrical connection region;
a reflection layer disposed on a sidewall of the trench;
a common electrode disposed in the electrical connection region; and
a first semiconductor stack disposed in the light-emitting region, wherein a first type semiconductor layer of the first semiconductor stack is electrically connected to the common electrode.

2. The light-emitting device of claim 1, wherein the carrier is a sapphire substrate.

3. The light-emitting device of claim 1, wherein a ratio of a depth of the trench to a thickness of the carrier ranges from 10% to 90%.

4. The light-emitting device of claim 1, wherein an included angle between the sidewall of the trench and a surface of the carrier ranges from 90 degrees to 110 degrees.

5. The light-emitting device of claim 1, wherein a reflectivity of the reflection layer is not less than 90%.

6. The light-emitting device of claim 1, wherein the carrier has a plurality of light-emitting regions, and adjacent light-emitting regions are separated by the trench.

7. The light-emitting device of claim 1, wherein the first type semiconductor layer is electrically connected to the common electrode through the reflection layer.

8. The light-emitting device of claim 1, wherein the first type semiconductor layer is electrically connected to the common electrode through its side surface or its surface facing away from the carrier.

9. The light-emitting device of claim 1, wherein the first semiconductor stack further includes a second type semiconductor layer, and the first type semiconductor layer is disposed between the second type semiconductor layer and the carrier.

10. The light-emitting device of claim 9, wherein the first semiconductor stack further includes a light-emitting layer, and the light-emitting layer is disposed between the first type semiconductor layer and the second type semiconductor layer.

11. The light-emitting device of claim 1, further comprising a second semiconductor stack, wherein the second semiconductor stack is disposed between the common electrode and the carrier.

12. The light-emitting device of claim 11, wherein a thickness of the second semiconductor stack is substantially the same as a thickness of the first semiconductor stack.

13. The light-emitting device of claim 1, further comprising a capping layer, which at least covers a sidewall of the first semiconductor stack.

14. The light-emitting device of claim 13, wherein the capping layer fills up the trench.

15. The light-emitting device of claim 1, wherein the reflection layer includes a Bragg reflector layer.

16. The light-emitting device of claim 1, further comprising an electrically conductive layer, wherein the reflection layer is disposed between the electrically conductive layer and the carrier, and the first type semiconductor layer is electrically connected to the common electrode through the electrically conductive layer.

17. A light-emitting apparatus, comprising:
a circuit substrate;
a carrier overlapping the circuit substrate and having an electrical connection region, a plurality of light-emitting regions and a plurality of trenches, wherein the plurality of trenches are disposed respectively between the electrical connection region and the plurality of light-emitting regions as well as between the plurality of light-emitting regions;
a reflection layer disposed on a sidewall of the trench;
a plurality of first semiconductor stacks disposed between the carrier and the circuit substrate and located respectively in the plurality of light-emitting regions; and
a common electrode disposed in the electrical connection region and electrically connecting first type semiconductor layers of the plurality of first semiconductor stacks to the circuit substrate.

18. The light-emitting apparatus of claim 17, wherein the common electrode is disposed between the carrier and the circuit substrate.

19. The light-emitting apparatus of claim 17, further comprising a first connector, which electrically connects the common electrode to the circuit substrate.

20. The light-emitting apparatus of claim 17, further comprising a second connector, which electrically connects a second type semiconductor layer of one of the plurality of first semiconductor stacks to the circuit substrate.

21. The light-emitting apparatus of claim 17, further comprising a color conversion layer, wherein the carrier is disposed between the color conversion layer and the circuit substrate.

22. The light-emitting apparatus of claim 21, wherein the color conversion layer includes a plurality of color conversion structures, which is overlapped with the plurality of first semiconductor stacks respectively.
